(19) United States
(12) Patent Application Publication
(10) Pub. No.: US 2008/0188048 A1
(43) Pub. Date: Aug. 7, 2008

(54) Semiconductor device

(75) Inventor: Takayuki Nagai, Kawasaki (JP)

Correspondence Address: YOUNG & THOMPSON, 209 Madison Street, Suite 500, ALEXANDRIA, VA, 22314, US

(73) Assignee: NEC ELECTRONICS CORPORATION, KAWASAKI (JP)

(21) Appl. No.: 12/073,488

(22) Filed: Mar. 6, 2008

Related U.S. Application Data
(62) Division of application No. 11/227,085, filed on Sep. 16, 2005, now abandoned.

(30) Foreign Application Priority Data
Sep. 28, 2004 (JP) 2004-282240

(51) Int. Cl. H01L 21/336

(52) U.S. Cl. 438/286; 438/301; 257/E21.435

(57) ABSTRACT

The invention provides a semiconductor apparatus capable of achieving a device having a snap-back resisting pressure of about 5 to 10 V by a self-aligning process. The semiconductor apparatus includes two or more sub-gates placed next to a main gate at a predetermined interval, and low concentration layers placed continuously from the ends of source/drain layers to near the end of the main gate, having a potential type same as that of the source/drain layers, and having an impurity concentration lower than that of the source/drain layers.

### BACKGROUND OF THE INVENTION

1. Field of the Invention

The present invention relates to a semiconductor apparatus comprising an MOS type transistor, and particularly to a semiconductor apparatus capable of achieving a device having a snap-back resisting pressure.

2. Description of Related Art

The purpose of securing a snap-back resisting pressure of about 5 to 10 V in a semiconductor apparatus comprising a transistor having a conventional LDD (Lightly Doped Drain) structure is often achieved by reducing the concentration of impurities in an LDD layer or situating a source/drain layer at a distance from a gate side end. Here, the snap-back resisting pressure means a Vd voltage abruptly increased by a phenomenon in which a drain current causes a bipolar operation, whereby an Id waveform of a Vd-Id characteristic is snap-backed (abruptly rebounds) when the Vd-Id characteristic is evaluated, and it is also called an on-resisting pressure.

However, if the concentration of impurities in the LDD layer is reduced, an on-current cannot be sufficiently secured due to a decrease in thickness of the LDD layer, and in the recent trend toward shallower (thinner) diffusion layers, it is often impossible to secure a snap-back resisting pressure of about 5 to 10 V merely by reducing the concentration of impurities.

If the source/drain layer is situated at a distance from the gate side end, a breakdown resisting pressure or snap-back resisting pressure can be determined somewhat freely, but an electrical characteristic is changed by slippage in a photoresist because ion implantation in formation of the source/drain layer is a non-self-aligning process.

Further, the above-mentioned problem and similar problems are found not only in the LDD structure but also in a DDD (Double Diffused Drain) structure and an extension structure.

It is conceivable that for securing a snap-back resisting pressure of 5 to 10 V in the semiconductor apparatus, a structure having an in-diffusion layer reverse conduction type diffusion layer in the diffusion layer (Resurf structure) is employed, for example, described by Japanese Patent Laid-Open No. 11-204792. Referring to FIG. 15, in a conventional semiconductor apparatus having the Resurf structure, an extension drain in-diffusion layer reverse conduction type diffusion layer (208; Resurf layer) formed under LOCOS may be formed between a main gate (202-1) and a sub-gate (202-2) by the self-aligning process using the main gate (202-1) and the sub-gate (202-2) as masks (see Patent Document 1). The Resurf structure is known as a high resisting pressure device, and is usually formed using a unique mask under LOCOS. In the Resurf structure, both wells as a lower layer and the Resurf layer as an upper layer are depleted on the drain side for achieving a high breakdown resisting pressure. Because the Resurf layer is formed by the self-aligning process, the sub-gate is used in addition to the main gate to form the Resurf layer between the main gate and the sub-gate using the main gate and the sub-gate as masks. Since the Resurf layer is formed on the source side as well, the Resurf layer on the drain side and the Resurf layer on the source side should be reverse conduction type layers. Namely, masks for forming the Resurf layer on the drain side and the Resurf layer on the source side should be formed separately on a substrate. A high resisting pressure device is suitable for making a Resurf structure because the size of the transistor is large compared with a low resisting pressure device.

However, if the Resurf structure is to be applied for making a transistor having a snap-back resisting pressure of about 5 to 10 V, the Resurf structure is not suitable for the high resisting pressure device because the size of the transistor becomes too large.

For achieving the Resurf structure, some degree of junction depth is required so that wells of the drain layer are linked under the sub-gate, but if such a junction depth is to be achieved in a transistor having a snap-back resisting pressure of about 5 to 10 V, a situation in which implanted ions pass through the gates (main gate and sub-gate) easily arises. Namely, if ion implantation for the drain layer is carried out until the junction depth is achieved, ions pass through the gate in the self-aligning process using the gate (polysilicon) as a mask. Therefore, for avoiding passage of ions through the gate, there is no choice but to make the junction depth relatively small.

From the standpoint described above, it is difficult to employ the Resurf structure in a transistor having snap-back resisting pressure of about 5 to 10 V.

In the conventional semiconductor apparatus having a Resurf structure, masks (photoresist) for forming the Resurf layer on the drain side and the Resurf layer on the source side should be formed separately on the substrate, but this is also a factor that increases the sizes of the main gate and the sub-gate. Thus, the technique of forming masks separately is not suitable for a transistor having a size.

### SUMMARY OF THE INVENTION

A first aspect of the present invention is a semiconductor apparatus comprising:

A MOS transistor of the present invention includes:

a main gate formed on a substrate; at least one sub gate placed next to the main gate formed on the substrate; a source/drain region formed on the substrate; and an impurity diffusion region placed continuously from the end of the source/drain layer to near the end of the main gate under the sub-gate, the impurity region having a conductivity type which is the same as that of the source/drain layer and having an impurity concentration lower than that of the source/drain layer.

A second aspect of the present invention is a method for producing a semiconductor apparatus, comprising the steps of:

forming a main gate and a sub-gate at a predetermined interval; and

forming a low concentration layer having a potential type same as that of a source/drain layer and having an impurity concentration lower than that of the source/drain layer in a well layer including a region under the sub-gate using the main gate and the sub-gate as masks by oblique rotation ion implantation.

A third aspect of the present invention is a method for producing a semiconductor apparatus, comprising the steps of:

forming a main gate and a sub-gate at a predetermined interval; and

implanting impurities having a potential type same as a source/drain layer and having a concentration lower than the source/drain layer into a well layer using the main gate and the sub-gate as masks, and diffusing the implanted impurities over a region under the sub-gate by a heating treatment to form a low concentration layer.

It is preferable that the method for producing a semiconductor apparatus comprises the steps of:

forming a side wall around the end-to-side surfaces of the main gate and the sub-gate; and

forming a source/drain layer by ion implantation using the main gate, the sub-gate and the side wall as masks.

According to the present invention, a transistor having a high breakdown resisting pressure and snap-back resisting pressure can be formed. At this time, the breakdown resisting pressure, the snap-back resisting pressure and the current capacity can be controlled easily with high accuracy.

According to the present invention, the number of sub-gates and the length of the sub-gate can be freely set.

According to the present invention, by changing an interval between the main gate and the sub-gate, control can be performed on existence/nonexistence of the source/drain layer therebetween, the concentration of the source/drain layer, and whether silicide is formed or not. Consequently, the breakdown resisting pressure, the snap-back resisting pressure and the current capacity can be freely controlled.

According to the present invention, the potentials of the main gate and the sub-gate can be freely set.

### BRIEF DESCRIPTION OF THE DRAWINGS

FIGS. 1A and 1B schematically show the configuration of a semiconductor apparatus according to the embodiment 1 of the present invention, wherein FIG. 1A is a partial plan view and FIG. 1B is a partial sectional view of a section of 1A-1A′;

FIGS. 2A to 2I are partial process sectional views schematically showing the first half of a method for producing the semiconductor apparatus according to the embodiment 1 of the present invention;

FIG. 3 is a partial plan view schematically showing an alteration of the configuration of the semiconductor apparatus according to the embodiment 1 of the present invention;

FIGS. 4A and 4B schematically show the configuration of the semiconductor apparatus according to the embodiment 2 of the present invention, wherein FIG. 4A is a partial plan view and FIG. 4B is a partial sectional view of a section of 4B-4B′;

FIGS. 5A to 5I are partial process sectional views schematically showing the first half of a method for producing the semiconductor apparatus according to the embodiment 2 of the present invention;

FIGS. 6A and 6B are graphs associated with a Vd-Id characteristic of the semiconductor apparatus using a gate size (Lpoly=0.6 μm), wherein FIG. 6A relates to the semiconductor apparatus according to a comparative example (using no sub-gates), and FIG. 6B relates to the semiconductor apparatus according to the embodiment 2 of the present invention (using sub-gates);

FIGS. 7A and 7B are graphs associated with the Vd-Id characteristic of the semiconductor apparatus having a source-drain distance (source-drain distance=2 μm), wherein FIG. 7A relates to the semiconductor apparatus according to a comparative example (using no sub-gates), and FIG. 6B relates to the semiconductor apparatus according to the embodiment 2 of the present invention (using sub-gates);

FIGS. 8A and 8B schematically show the configuration of the semiconductor apparatus according to the embodiment 3 of the present invention, wherein FIG. 8A is a partial plan view and FIG. 8B is a partial sectional view of a section of 8C-8C′;

FIG. 9 is a partial plan view schematically showing the configuration of the semiconductor apparatus according to the embodiment 4 of the present invention;

FIG. 10 is a partial sectional view schematically showing the configuration of the semiconductor apparatus according to the embodiment 6 of the present invention;

FIG. 11 is a partial sectional view schematically showing the configuration of the semiconductor apparatus according to the embodiment 7 of the present invention;

FIG. 12 is a partial sectional view schematically showing the configuration of the semiconductor apparatus according to the embodiment 8 of the present invention;

FIG. 13 is a partial sectional view schematically showing an alteration of the configuration of the semiconductor apparatus according to the embodiment 8 of the present invention;

FIGS. 14A and 14B schematically show the configuration of the semiconductor apparatus according to the embodiment 9 of the present invention, wherein FIG. 14A is a partial plan view and FIG. 14B is a partial sectional view of a section of 14D-14D′; and

FIG. 15 is a partial sectional view schematically showing the configuration of the semiconductor apparatus according to one example of a conventional technique.

### DETAILED DESCRIPTION OF THE PREFERRED EMBODIMENTS

### Embodiment 1

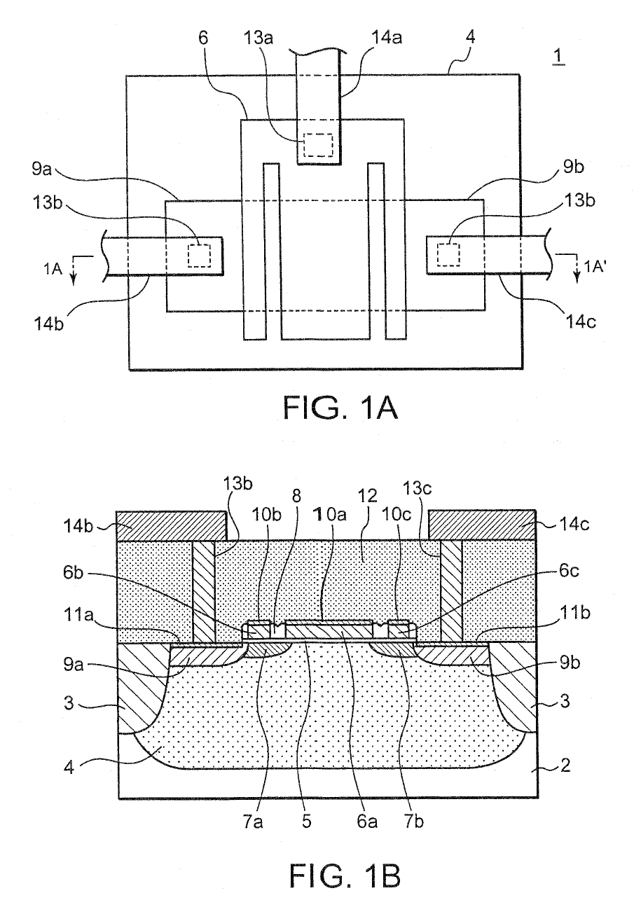

The embodiment 1 of the present invention will be described using the drawings. FIGS. 1A and 1B schematically show the configuration of a semiconductor apparatus according to the embodiment 1 of the present invention, wherein FIG. 1A is a partial plan view and FIG. 1B is a partial sectional view of a section of 1A-1A′. Here, the case of NMOS will be described.

The semiconductor apparatus 1 is a semiconductor apparatus having an NMOS type transistor, and comprises a silicon substrate 2, a element separating region 3, a well layer 4, a gate insulating film 5, a gate 6, an lightly doped drain (LDD) layer 7, a side wall 8, a source/drain layer 9, silicide layers 10, 11, an interlayer insulating film 12, a contact plug 13 and a wiring layer 14.

The silicon substrate 2 is a P type silicon substrate. The element separating region 3 is a region electrically separating a plurality of device active regions (elements) formed on the silicon substrate 2. The element separating region 3 is composed of an insulating material (e.g. silicon oxide film), and is placed at a location surrounding the device active regions in a predetermined depth. The well layer 4 is a region where P type impurities (e.g. boron ions) are diffused into the silicon substrate 2 to a predetermined depth for each device active area. The gate insulating film 5 is an insulating film (silicon oxide film) that is used in a region where gates 6, 6a, 6b and 6c are placed on the silicon substrate 2.

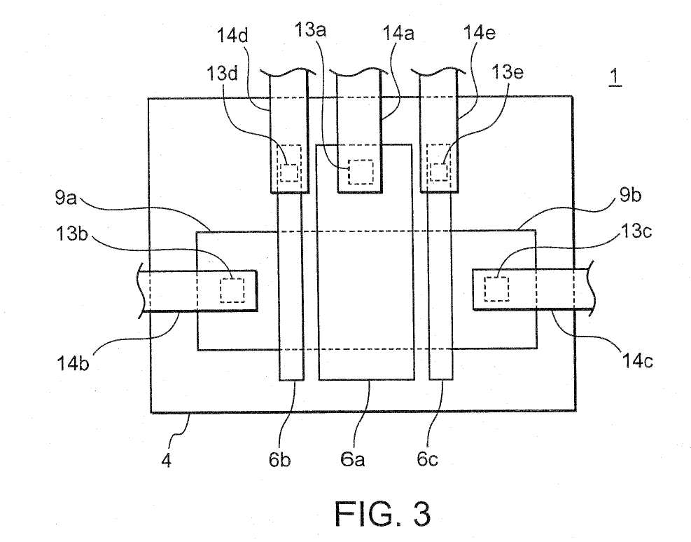

The gate 6 is placed on the gate insulating film 5 and between the source and the drain (source/drain layer 9a, 9b), is composed of polysilicon, and has the main gate 6a and the sub-gates 6b and 6c. The main gate 6a is a gate for channel control. The sub-gates 6b and 6c (total two sub-gates) are placed next to the main gate 6a on both sides at a predetermined interval with one sub-gate on one side, and linked integrally with the main gate 6a at a predetermined site. Intervals between the main gate 6a and the sub-gates 6b, 6c have lengths such that the side walls of the main gate 6a and the sub-gates 6b, 6c (walls formed in regions between the main gate 6a and the sub-gates 6b, 6c) mutually contact the gates during formation of the side wall 8, and spaces between the main gate 6a and the sub-gates 6b, 6c are filled with the side wall 8. The main gate 6a and the sub-gates 6b, 6c can be brought closer together to the extent that the limit of PR (photoresist) exposure is reached. Source/drain layers 9a, 9b being impurity high concentration diffusion layers do not exist in regions between the main gate 6a and the sub-gates 6b, 6c when seen from the two-dimensional direction. The sub-gates 6b, 6c should be sufficiently reduced so that LDD layers 7a, 7b can be formed under the sub-gates 6b, 6c. The main gate 6a and the sub-gates 6b, 6c may be mutually separated without being electrically connected, and controlled individually (see FIG. 3). For example, for securing a non-current wherever possible, the source/drain layer 9a and the sub-gate 6b may be electrically connected to each other. This is because the LDD layer exists under the sub-gate 6b (7a in FIG. 1B), and by setting the potential of the sub-gate 6b, a carrier in the LDD layer 7a can be freely controlled. Silicide layers 10a, 10b and 10c (e.g. TiSi) are formed on the surfaces of the main gate 6a and the sub-gates 6b, 6c on the interlayer insulating film 12 side. No silicide layers 10a, 10b and 10c may be provided as required.

LDD layers 7a, 7b are low concentration diffusion layers (N-type diffusion layer; e.g. phosphorous ion low concentration diffusion layer) formed in the well layer 4 and under the sub-gates 6b, 6c and having a potential type same as that of the source/drain layers 9a, 9b. The LDD layer 7a extends continuously from near the end of the sub-gate 6b on the left side to near the end of the main gate 6a on the left side when seen from the two-dimensional direction. The LDD layer 7b extends from near the end of the sub-gate 6c on the right side to near the end of the main gate 6a on the right side when seen from the two-dimensional direction. The reason why the LDD structure is selected is as follows. In the embodiment 1, a Resurf structure is not used, and therefore the depth of a junction cannot be increased. If the depth of the junction is increased, ions pass through the gates, and therefore implantation by the self-aligning method cannot be performed. Thus, the LDD structure is selected. The reason why the LDD layers 7a, 7b are also formed under the sub-gates 6b, 6c is as follows. In the LDD structure, it is necessary to change the concentrations of the LDD layers 7a, 7b for controlling the breakdown resisting pressure and the snap-back resisting pressure. However, the lengths of the LDD layers 7a, 7b cannot be normally controlled so well, and changes in breakdown resisting pressure and snap-back resisting pressure are limited even though the concentrations are changed. If a structure using the sub-gates 6b, 6c is applied, the source/drain layers 9a, 9b and the main gate 6a are separated, and the characteristic of the transistor is not exhibited, or the transistor has a very poor electrical characteristic if the sub-gates 6b, 6c are merely formed. Thus, the LDD layers 7a, 7b are also formed under the sub-gates 6b, 6c. For obtaining a transistor having a higher breakdown resisting pressure and snap-back resisting pressure, it is necessary to reduce the concentrations of the LDD layers 7a, 7b.

The side wall 8 is an insulating area (e.g. silicon oxide film) formed around side edges of the main gate 6a and the sub-gates 6b, 6c, and in regions between the main gate 6a and the sub-gates 6b, 6c, the side wall 8 mutually contacts to fill the regions. The side wall 8 between the main gate 6a and the sub-gates 6b, 6c serves as a mask for preventing formation of the source/drain layers 9a, 9b in regions between the main gate 6a and the sub-gates 6b, 6c.

The source/drain layers 9a, 9b are high concentration diffusion layers (N+ type diffusion layer; e.g. arsenic ion high concentration diffusion layer) formed in the well layer 4 outside the sub-gate 6b on the left and outside the sub-gate 6c on the right and having a potential type same as that of the LDD layers 7a, 7b. The source drain layer 9a is connected to the LDD layer 7a at near the left end of the sub-gate 6b. The source/drain layer 9b is connected to the LDD layer 7b at near the right end of the sub-gate 6c. The source/drain layers 9a, 9b are not formed in regions between the main gate 6a and the sub-gates 6b, 6c when seen from the two-dimensional direction. The drain/source layers 9a, 9b are kept at a distance from the main gate 6a by the sub-gates 6b, 6c and the side wall 8. As a result of placement of the source/drain layers 9a, 9b at a distance from the main gate 6a, only the LDD layers 7a, 7b exist between the ends of the source/drain layers 9a, 9b and the main gate 6a. Placement of the source/drain layers 9a, 9b at a distance from the main gate 6a is for the purpose of obtaining a transistor having a high breakdown resisting pressure and snap-back resisting pressure. Silicide layers 11a, 11b (e.g. TiSi) are formed on the surfaces of the source/drain layers 9a, 9b on the interlayer insulating film 12 side. It may be unnecessary to provide the silicide layers 11a, 11b as required.

The interlayer insulating film 12 is an insulating layer (e.g. silicon oxide film) formed on the surfaces of the element separating region 3, the side wall 8, silicide layers 10a, 10b, 10c, 11a, 11b. A plurality of contact holes communicating with the silicide layers 10a, 11a, 11b are formed in the interlayer insulating film 12. Contact plugs 13a, 13b, 13c are conductive layers (e.g. W) connected to the silicide layers 10a, 11a, 11b, respectively, and are formed in the contact holes of the interlayer insulating film 12. Wiring layers 14a, 14b, 14c are conductive layers (e.g. Al) connected to the contact plugs 13a, 13b, 13c, respectively, and are formed on the surface of the interlayer insulating film 12 in a predetermined pattern.

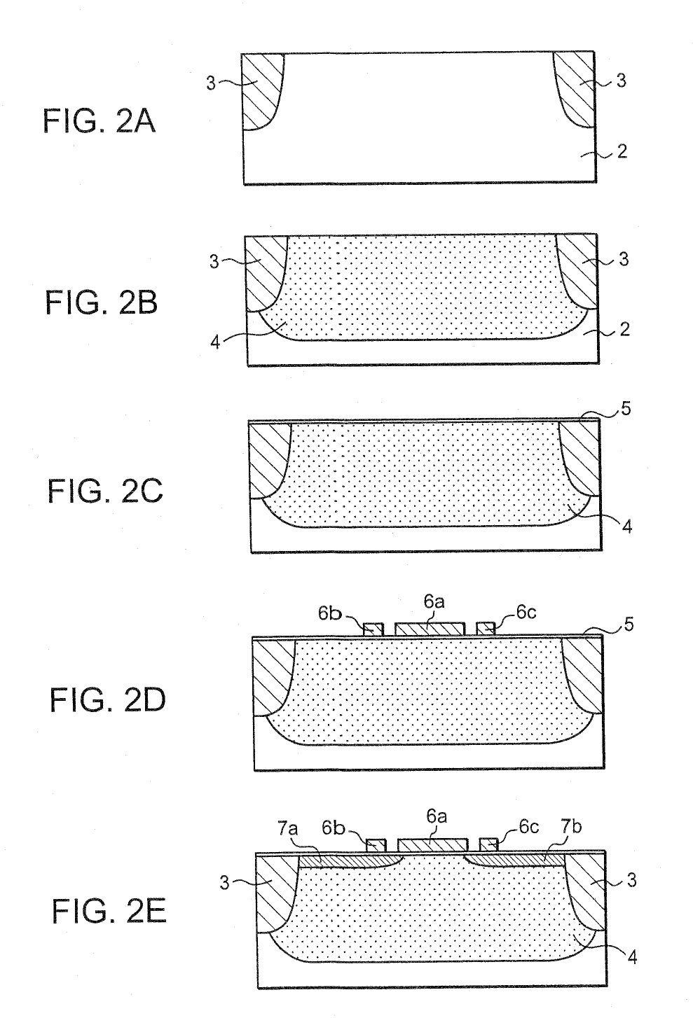

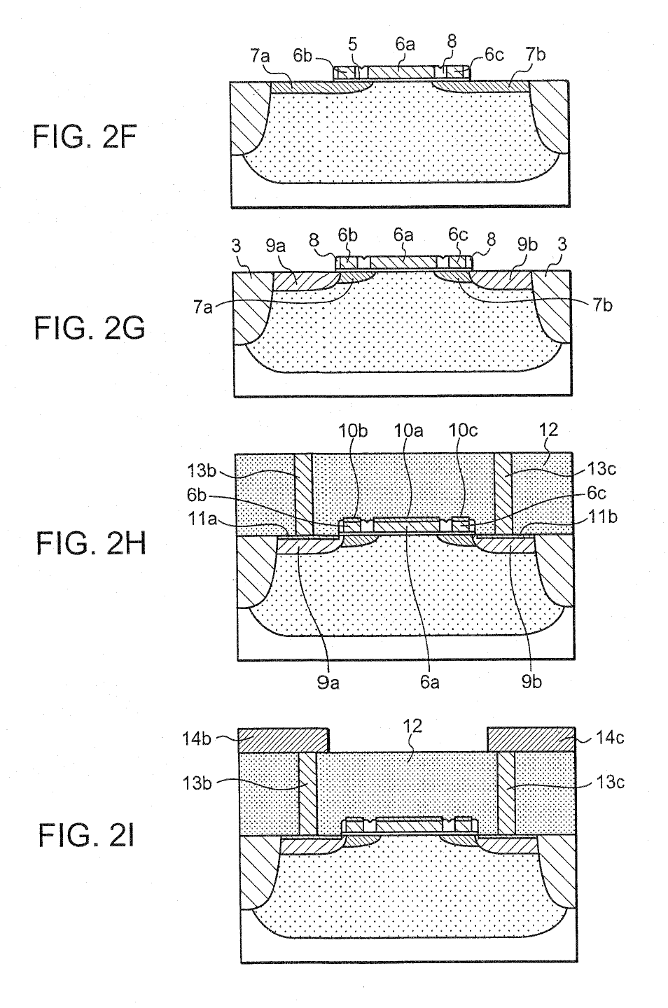

A method for producing the semiconductor apparatus according to the embodiment 1 will now be described. FIGS. 2A to 2I are partial process sectional views schematically showing the method for producing the semiconductor apparatus according to the embodiment 1 of the present invention. Here, the case of forming an NMOS will be described.

First, the silicon substrate 2 is prepared, and the element separating region 3 is formed at a predetermined location on the silicon substrate 2 (step A1; see FIG. 2A). Here, for the silicon substrate 2, for example, a P type silicon substrate having a resistivity of 15 O·cm is used. The element separating region 3 is composed of a silicon oxide film, and can be formed by the LOCOS (Local Oxidation of Silicon) method or STI (Shallow Trench Isolation) method. The depth of the element separating region 3 is about 0.1 to 5 μm.

Then, the well layer 4 is formed on the silicon substrate 2 (step A2; see FIG. 2B). The well layer 4 is a P type well, and is formed by, for example, implanting boron (B) ions. For implantation conditions, for example, the ion implantation energy (accelerating energy) is 400 KeV, the ion implantation dose amount is 1×10¹³/cm², the ion implantation energy (accelerating energy) is 100 KeV, and the ion implantation dose amount is 5×10¹²/cm². Ions are implanted into a silicon region surrounded by the element separating region 3 when seen from the two-dimensional direction.

Then, the gate insulating film 5 is formed on the surface of the well layer 4 (step A3; see FIG. 2C). Here, the gate insulating film 5 is, for example, a silicon oxide film, and has a thickness of 16 nm.

Then, the main gate 6a and the sub-gates 6b, 6c are formed at predetermined locations on the surface of the gate insulating film 5 (step A4; see FIG. 2D). Here, for example, polysilicon for gates 6a, 6b, 6c is grown to a thickness of 200 nm on the entire surface of the gate insulating film (5 in FIG. 2C), a photoresist (not shown) is formed on the surface of polysilicon in a predetermined mask pattern, polysilicon in regions exposed from the mask pattern is etched away until the gate insulating film 5 appears, and the photoresist is then removed. The intervals between the main gate 6a and the sub-gates 6b, 6c are, for example, 0.2 μm so that the side walls 8 of the main gate 6a and the sub-gates 6b, 6c mutually contact when the side wall 8 is formed in the subsequent step (see FIG. 2F). The gate insulating film 5 associated with regions other than the regions of the main gate 6a and the sub-gates 6b, 6c when seen from the two-dimensional direction may be etched away after the main gate 6a and the sub-gates 6b, 6c are formed and before the photoresist is removed.

Then, the LDD layers 7a, 7b are formed in predetermined regions in the well layer 4 (step A5; see FIG, 2E). The LDD layers 7a, 7b are N type diffusion layers, and are formed under the sub-gates 6b, 6c by oblique rotation ion implantation using phosphorous (P) ions by the self-aligning process with the main gate 6a and the sub-gates 6b, 6c as masks. For implantation conditions at this time, for example, the ion implantation energy is 50 KeV, the ion implantation dose amount is 1×10¹³/cm², and the ion implantation angle is 30°. Formation of the LDD layers 7a, 7b by oblique rotation ion implantation is for the purpose of forming the continuous LDD layers 7a, 7b also under the sub-gates 6b, 6c to increase the breakdown resisting pressure and snap-back resisting pressure of the transistor. Ions are implanted from regions between the element separating region 3 and the sub-gate 6b, between the sub-gate 6b and the main gate 6a, between the main gate 6a and the sub-gate 6c and between the sub-gate 6c and the element separating region 3. The continuous LDD layers 7a, 7b can also be formed under the sub-gates 6b, 6c by using 0° implantation instead of oblique rotation ion implantation, followed by thermally diffusing phosphorous ions implanted by a heat treatment (annealing).

Then, the side wall 8 is formed around the side edges of the main gate 6a and the sub-gates 6b, 6c (step A6; see FIG. 2F). For the side wall 8, for example, a silicon oxide film is used, and its thickness is 150 nm. The side wall 8 can be formed by, for example, depositing the silicon oxide film on the surface of the substrate, and then etching back the silicon oxide film until the surfaces of the main gate 6a, the sub-gates 6b, 6c and the LDD layers 7a, 7b appear. Because spaces between the main gate 6a and the sub-gates 6b, 6c are small, the side walls 8 of the main gate 6a and the sub-gates 6b, 6c mutually contact, and gaps between the main gate 6a and the sub-gates 6b, 6c are filled with the side wall 8.

Then, source/drain layers 9a, 9b are formed in predetermined regions of the LDD layers 7a, 7b (step A7; see FIG. 2G). The source/drain layers 9a, 9b are N type diffusion layers, and can be formed by, for example, ion implantation using arsenic (As) ions by the self-aligning process with the main gate 6a, the sub-gates 6b, 6c and the side wall 8 as masks. For implantation conditions at this time, for example, the ion implantation energy is 50 KeV, and the ion implantation dose amount is 1×10¹⁵/cm². Ions are implanted from regions between the element separating region 3 and the sub-gates 6b, 6c when seen from the two-dimensional direction. Because spaces between the main gate 6a and the sub-gates 6b, 6c are filled with the side wall 8 with their side walls 8 contacting one another, ions same as ions of the source/drain layers 9a, 9b are not implanted from the regions between the main gate 6a and the sub-gates 6b, 6c when seen from the two-dimensional direction.

Then, silicide layers 10a, 10b, 10c, 11a, 11b are formed on the surfaces of the gates 6a, 6b, 6c and the source drain layers 9a, 9b, the interlayer insulating film 12 is formed on the entire surface of the substrate, contact holes communicating with the silicide layers 10a, 11a, 11b are formed in the interlayer insulating film 12, and contact plugs 13a, 13b, 13c corresponding to the silicide layers 10a, 11a, 11b, respectively, are formed in the contact holes (step A8; see FIG. 1A and FIG. 2H). The silicide layers 10a, 10b, 10c, 11a, 11b can be formed by, for example, carrying out silicide formation processing using Ti. Because spaces between the main gate 6a and the sub-gates 6b, 6c are filled with the side wall 8, the surfaces of the LDD layers 7a, 7b do not undergo a silicide formation reaction. The contact plugs 13a, 13b, 13c can be formed by, for example, forming a tungsten layer on the surface of the interlayer insulating film 12 including contact holes and subjecting the tungsten layer to CMP or etching back the tungsten layer until the interlayer insulating film 12 appears.

Finally, wiring layers 14a, 14b, 14c are formed corresponding to the contact plugs 13a, 13b, 13c, respectively, are formed on the interlayer insulating film 12 (step A9; see FIG. 1A and FIG. 2I). The wiring layers 14a, 14b, 14c are formed by, for example, an aluminum layer is deposited on the surface of the interlayer insulating film 12 including the contact plugs 13a, 13b, 13c, forming a photoresist (not shown) in a predetermined mask pattern, etching away the aluminum layer in regions exposed from the mask pattern until the interlayer insulating film 12 appears, and then removing the photoresist. In this way, a semiconductor apparatus having a transistor having a desired structure is formed.

According to the embodiment 1, compared with the case of using one gate, the LDD layers 7a, 7b have increased lengths and plays a role of alleviating electrical fields extending from the ends of the source/drain layers 9a, 9b to below the main gate 6a, thus making it possible to secure a high breakdown resisting pressure and a snap-back resisting pressure.

Because the LDD layers 7a, 7b and source/drain layers 9a, 9b of a semiconductor apparatus having a transistor having a high breakdown resisting pressure and snap-back resisting pressure can be formed by the self-aligning process, the semiconductor apparatus can be produced without adding a PR step.

By selecting the LDD structure without using the Resurf structure, a semiconductor having a transistor with stable properties can be produced using the self-aligning process. Namely, by reducing the ion implantation intensity to decrease the junction depth of the diffusion layers (LDD layers 7a, 7b) under the sub-gates 6b, 6c, implantation by the self-aligning process can be performed while avoiding the conventional problem such that ions pass through the gate.

Because the Resurf structure is not used, the source/drain layers 9a, 9b implanted into the NMOS are only of N+ type. Namely, it is not necessary to switch between masks for formation of the source/drain layers 9a, 9b on the main gate 6a and the sub-gates 6b, 6c as in the Resurf structure, and the lengths of the main gate 6a and sub-gates 6b, 6c can be sufficiently reduced. Therefore, the size of the transistor can be sufficiently reduced. A same effect is obtained when the method is applied to the PMOS (source/drain layers 9a, 9b are only of P+ type).

Because the LDD layers 7a, 7b are formed under the sub-gates 6b, 6c by oblique rotation ion implantation for increasing the breakdown resisting pressure and snap-back resisting pressure of the transistor, the LDD layers 7a, 7b extending to near the end of the main gate 6a are connected to the source/drain layers 9a, 9b, respectively, and thus good characteristics as a transistor are obtained.

Electrical fields extending from the ends of the source/drain layers 9a, 9b to below the end of the main gate 6a are maximally alleviated by the LDD layers 7a, 7b which are low concentration layers, thus making it possible to obtain a high breakdown resisting pressure and snap-back resisting pressure.

Further, silicide formation on the surfaces of the source/drain layers 9a, 9b of transistors which have been in the mainstream in recent years can be controlled. Namely, because spaces between the main gate 6a and the sub-gates 6b, 6c are filled with the sidewall 8, no silicide reaction occurs, and thus the side wall 8 can be used as a high-precision silicide block in the self-aligning process.

In the embodiment 1, the semiconductor apparatus using a P type silicon substrate for the substrate 2 is described, but the present invention can be applied to a semiconductor apparatus using an N type silicon substrate.

### Embodiment 2

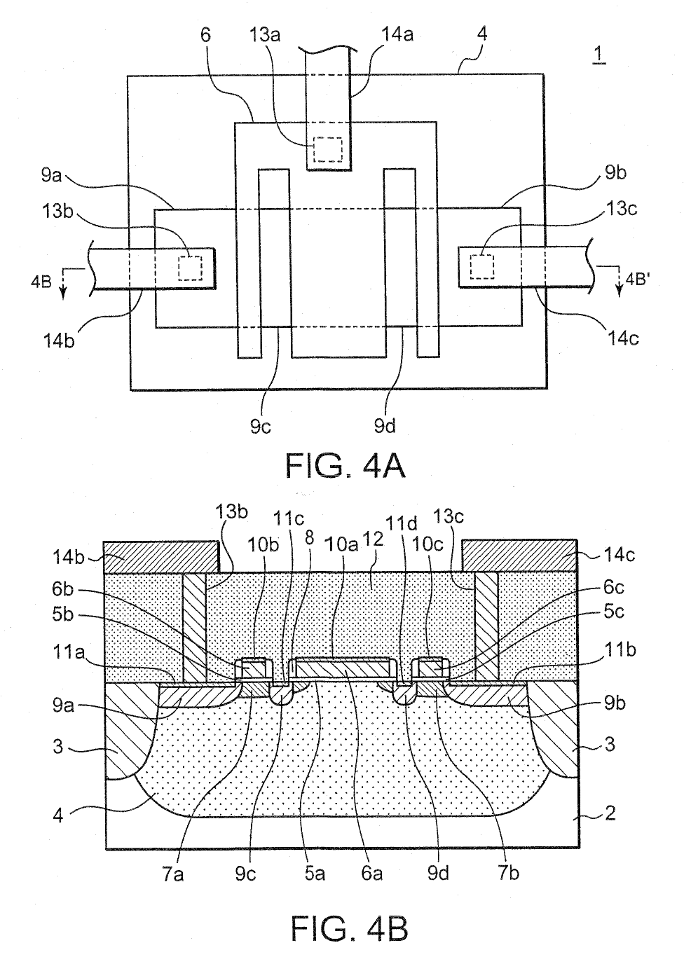

The embodiment 2 of the present invention will be described using the drawings. FIGS. 4A and 4B schematically show the configuration of the semiconductor apparatus according to the embodiment 2 of the present invention, wherein FIG. 4A is a partial plan view and FIG. 4B is a partial sectional view of a section of 4B-4B′.

In the semiconductor apparatus according to the embodiment 2, source/drain layers 9c, 9d are locally formed between the main gate 6a and the sub-gates 6b, 6c when seen from the two-dimensional direction, and the side walls 8 of the main gate 6a and the sub-gates 6b, 6c are independent and do not mutually contact. Consequently, ions can be implanted from regions between the main gate 6a and the sub-gates 6b, 6c, thus making it possible to form source/drain layers 9c, 9d having concentrations higher than the concentrations of the LDD layers 7a, 7b. Silicide layers 11c, 11d are formed on the surfaces of the source/drain layers 9c, 9d on the interlayer insulating film 12 side. The source/drain layer 9c separates the LDD layer 7a, and the source/drain layer 9d separates the LDD layer 7b. Other respects of configuration are same as those of the embodiment 1.

Formation of the source/drain layers 9c, 9d of ions identical to the ions of the source/drain layers 9a, 9b between the main gate 6a and the sub-gates 6b, 6c is for the purpose of inhibiting the disadvantage that the quantity of on-current decreases. Namely, the LDD layers 7a, 7b have a high resistance compared with the source/drain layers 9a, 9b, and the on-current decreases if the LDD layers 7a, 7b are merely extended. For avoiding this, it is conceivable that the concentrations of the LDD layers 7a, 7b are increased or the lengths of the LDD layers 7a, 7b are reduced. However, if the concentrations of the LDD layers 7a, 7b are increased, the role of alleviating electrical fields is diminished, resulting in a decrease in breakdown resisting pressure. Reduction of the lengths of the LDD layers 7a, 7b means reduction of the lengths of the sub-gates 6b, 6c, and it is possible until the limit for a light exposing apparatus such as a stepper is reached, but it is impossible above the limit in principle. Thus, the source/drain layers 9c, 9d and silicide layers 11c, 11d as high concentration layers are added to part of the LDD layer. It may be unnecessary to provide the layers 11c, 11d as required.

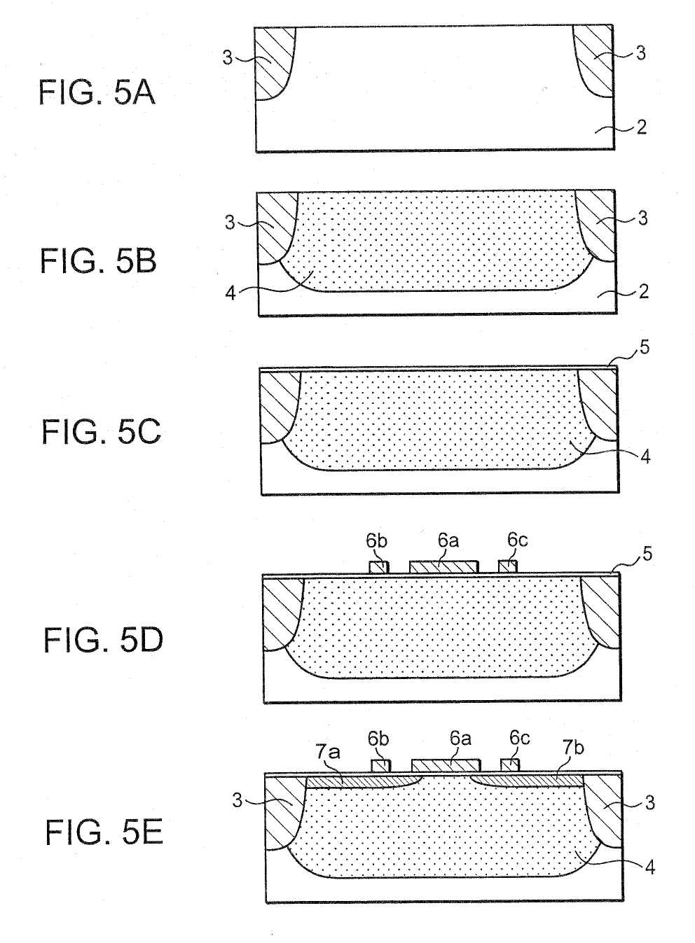

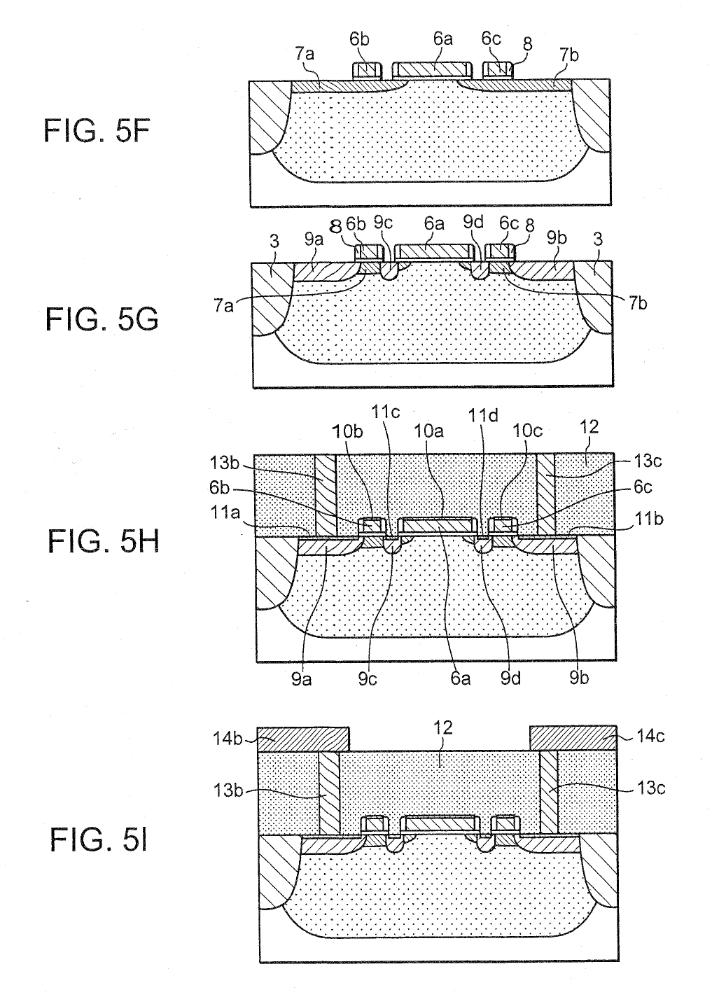

The method for producing the semiconductor apparatus according to the embodiment 2 will now be described. FIGS. 5A to 5I are partial process sectional views schematically showing the method for producing the semiconductor apparatus according to the embodiment 2 of the present invention. Here, the case of forming the NMOS will be described.

First, the element separating region 3 is formed at a predetermined location on the silicon substrate 2 (step B1; see FIG. 5A), the well layer 4 is formed on the silicon substrate 2 (step B2; see FIG. 5B), and the gate insulating film 5 is formed on the surface of the well layer 4 (step B3; see FIG. 5C). Steps B1 to B3 are similar to steps A1 to A3 of the embodiment 1.

Then, the main gate 6a and the sub-gates 6b, 6c are formed at predetermined locations on the surface of the gate insulating film 5 (step B4; see FIG. 5D). Here, for example, polysilicon for the gates 6a, 6b, 6c is grown to a thickness of 200 nm over the entire surface of the gate insulating film (5 in FIG. 5C), a photoresist (not shown) is formed on the surface of polysilicon in a predetermined mask pattern, polysilicon in regions exposed from the mask pattern are etched away, and the photoresist is then removed. Spaces between the main gate 6a and the sub-gates 6b, 6c are, for example, 0.5 μm so that the side walls 8 of the main gate 6a and the sub-gates 6b, 6c do not mutually contact when the side wall 8 is formed in the subsequent step (see FIG. 5F). The gate insulating film 5 associated with regions other than the regions of the main gate 6a and the sub-gates 6b, 6c when seen from the two-dimensional direction after the main gate 6a and the sub-gates 6b, 6c are formed and before the photoresist is removed.

Then, LDD layers 7a, 7b are formed in predetermined regions in the well layer 4 (step B5; see FIG. 5E). Step B5 is similar to step A5 of the embodiment 1.

Then, the side wall 8 is formed around the side edges of the main gate 6a and the sub-gates 6b, 6c (step B6; see FIG. 5F). For the side wall 8, a silicon oxide film is used, and its thickness is 150 nm. The side wall 8 can be formed by, for example, depositing the silicon oxide film on the surface of the substrate, and then etching back the silicon oxide film until the surfaces of the main gate 6a, the sub-gates 6b, 6c and the LDD layers 7a, 7b appear. Because spaces between the main gate 6a and the sub-gates 6b, 6c are increased, the side walls 8 of the main gate 6a and the sub-gates 6b, 6c do not mutually contact, and there are areas where the LDD layers 7a, 7b are exposed between the main gate 6a and the sub-gates 6b, 6c.

Then, source/drain layers 9a, 9b, 9c, 9d are formed in predetermined regions of the LDD layers 7a, 7b (step B7; see FIG. 5G). The source/drain layers 9a, 9b, 9c, 9d are N type diffusion layers, and can be formed by, for example, ion implantation using arsenic (As) ions by the self-aligning process. For implantation conditions at this time, for example, the ion implantation energy is 50 KeV, and the ion implantation dose amount is 1×10¹⁵/cm². Ions are implanted from regions between the element separating region 3 and the sub-gate 6b, between the sub-gate 6b and the main gate 6a, between the main gate 6a and the sub-gate 6c and between the sub-gate 6c and the element separating region 3 when seen from the two-dimensional direction. Consequently, the source/drain layer 9a and the source/drain layer 9c are separated by the LDD layer 7a, and the source/drain layer 9b and the source/drain layer 9d are separated by the LDD layer 7b. The LDD layer 7a is separated by the source/drain layer 9c, and the LDD layer 7b is separated by the source/drain layer 9d.

Then, silicide layers 10a, 10b, 10c, 11a, 11b, 11c, 11d are formed on the surfaces of the gates 6a, 6b, 6c and the source/drain layers 9a, 9b, 9c, 9d, the interlayer insulating film 12 is formed on the entire surface of the substrate, contact holes communicating with the silicide layers 10a, 11a, 11b are formed, and contact plugs 13a, 13b, 13c corresponding to the silicide layers 10a, 11a, 11b are formed in the contact holes (step B8; see FIGS. 4A and 5H). The silicide layers 10a, 10b, 10c, 11a, 11b, 11c, 11d can be formed by, for example, carrying out silicide formation processing using Ti. The side wall 8 is not continuous in spaces between the main gate 6a and the sub-gates 6b, 6c, and therefore the silicide layers 11c, 11d are formed on the surfaces of the source/drain layers 9c, 9d. The contact plugs 13a, 13b, 13c can be formed by, for example, forming a tungsten layer on the surface of the interlayer insulating film 12 including the contact holes, and subjecting the tungsten layer to CMP or etching back the tungsten layer until the interlayer insulating film 12 appears.

Finally, wiring layers 14a, 14b, 14c corresponding to the contact plugs 13a, 13b, 13c are formed on the surface of the interlayer insulating film 12 (step B9; see FIGS. 4A and 5I). Step 9B is similar to step A9 of the embodiment 1. As a result, a semiconductor apparatus having a transistor having a desired structure is formed.

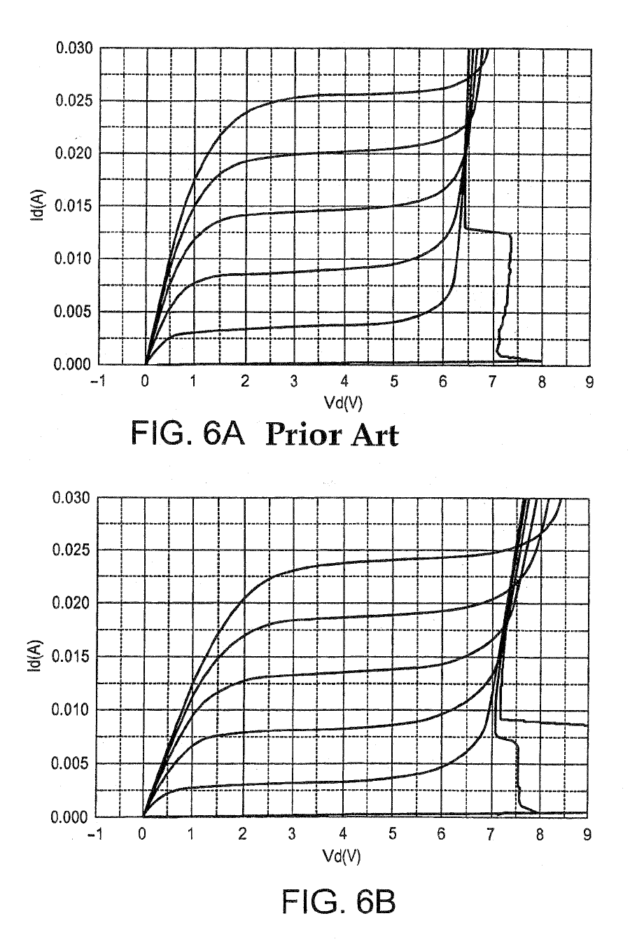

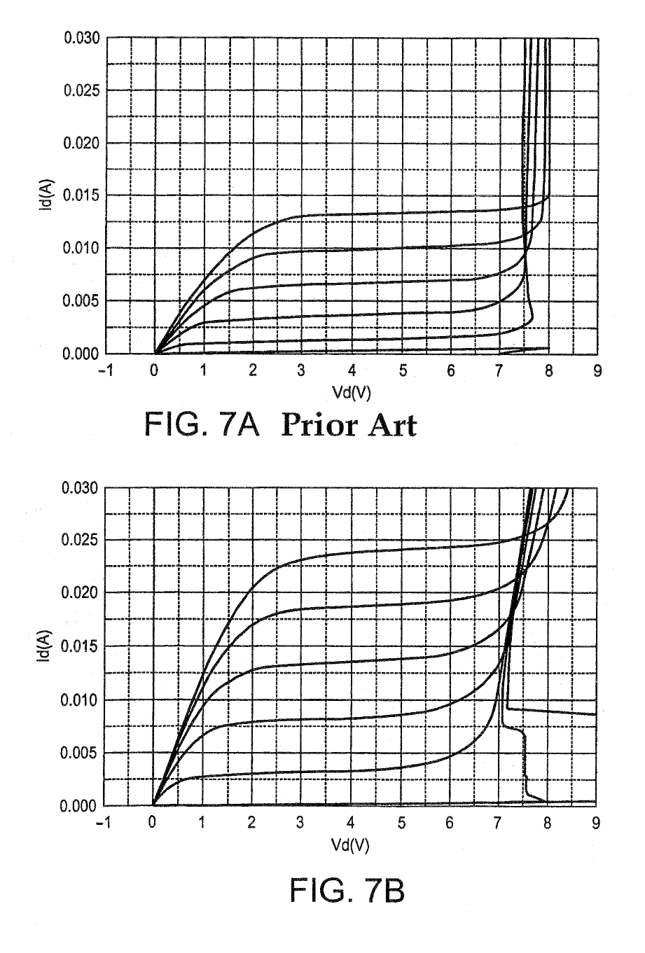

The Vd-Id characteristic of the semiconductor apparatus according to the embodiment 2 will now be described. FIGS. 6A and 6B are graphs associated with the Vd-Id characteristic of the semiconductor apparatus using a gate (main gate) size (Lpoly=0.6 μm), wherein FIG. 6A relates to the semiconductor apparatus according to a comparative example (using no sub-gates), and FIG. 6B relates to the semiconductor apparatus according to the embodiment 2 of the present invention (using sub-gates). FIGS. 7A and 7B are graphs associated with the Vd-Id characteristic of the semiconductor apparatus having a source-drain distance (source-drain distance=2 μm), wherein FIG. 7A relates to the semiconductor apparatus according to a comparative example (using no sub-gates), and FIG. 7B relates to the semiconductor apparatus according to the embodiment 2 of the present invention (using sub-gates).

Referring to FIGS. 6A and 6B, the semiconductor apparatus according to the embodiment 2 (FIG. 6B) has a higher LDD resistance and accordingly has a less on-current compared with the semiconductor apparatus according to the comparative example (FIG. 6A), but can be found to have an improved snap-back voltage. Referring to FIGS. 7A and 7B, the semiconductor apparatus according to the embodiment 2 (FIG. 7B) has a slightly lower snap-back voltage compared with the semiconductor apparatus according to the comparative example (FIG. 7A), but can be found to be capable of securing a very large quantity of on-current.

Accordingly, according to the embodiment 2, the advantage that the snap-back voltage is higher for the same gate size and a larger quantity of on-current can be secured for the same transistor size can be obtained (see FIGS. 6A and 6B and 7A and 7B).

The LDD layers 7a, 7b have increased lengths compared with the case of using one gate to form the LDD layers, and thus play a role of alleviating electrical field extending from the ends of the source/drain layers 9a, 9b to below the main gate 6a, thus making it possible to secure a high breakdown resisting pressure and snap-back resisting pressure. The LDD layers 7a, 7b have high electrical resistances compared with the source/drain layers 9a, 9b, resulting in a decrease in quantity of on-current. For compensating this, source drain layers 9c, 9d into which ions same as the ions of the source/drain layers 9a, 9b have been implanted are locally formed between the main gate 6a and the sub-gates 6b, 6c, and the source/drain layers 9c, 9d play a role of reducing the electrical resistances of the LDD layers 7a, 7b. As a result, the breakdown resisting pressure and the snap-back resisting pressure are increased, and the on-current can be secured in a relatively large quantity.

Because the layers can be formed by the self-aligning process, a semiconductor apparatus having a transistor having a high breakdown resisting pressure and snap-back resisting pressure can be produced without adding the PR step.

By selecting the LDD structure without using the Resurf structure, a semiconductor having a transistor with stable properties can be produced using the self-aligning process. Namely, by reducing the ion implantation intensity to decrease the junction depth of the diffusion layers (LDD layers 7a, 7b) under the sub-gates 6b, 6c, implantation by the self-aligning process can be performed while avoiding the conventional problem such that ions pass through the gate.

Because the Resurf structure is not used, the source/drain layers 9a, 9b, 9c, 9d implanted into the NMOS are only of N+ type. Namely, it is not necessary to switch between masks for formation of the source/drain layers 9a, 9b, 9c, 9d on the main gate 6a and the sub-gates 6b, 6c as in the Resurf structure, and the lengths of the main gate 6a and sub-gates 6b, 6c can be sufficiently reduced. Therefore, the size of the transistor can be sufficiently reduced. A same effect is obtained when the method is applied to the PMOS (source/drain layers 9a, 9b, 9c, 9d are only of P+ type).

Because the LDD layers 7a, 7b are formed under the sub-gates 6b, 6c by oblique rotation ion implantation for increasing the breakdown resisting pressure and snap-back resisting pressure of the transistor, the LDD layers 7a, 7b extending to near the end of the main gate 6a are connected to the source/drain layers 9a, 9b, respectively, and thus good characteristics as a transistor are obtained.

By adding high concentration layers (source/drain layers 9c, 9d) to part of the LDD layers 7a, 7b, the whole resistance can be reduced to minimize the decrease in quantity of on-current. Silicide layers 11c, 11d are formed between the main gate 6a and the sub-gates 6b, 6c, whereby the electrical resistance can be further reduced. As a result, a transistor having a high breakdown resisting pressure and snap-back resisting pressure, and securing a larger quantity of on-current compared to the embodiment 1, and capable of being formed by the self-aligning process can be formed without adding the PR step.

The source/drain layers 9a, 9b, 9c, 9d and silicide layers can be added by the self-aligning process, and a desired structure can be obtained without adding the PR step.

### Embodiment 3

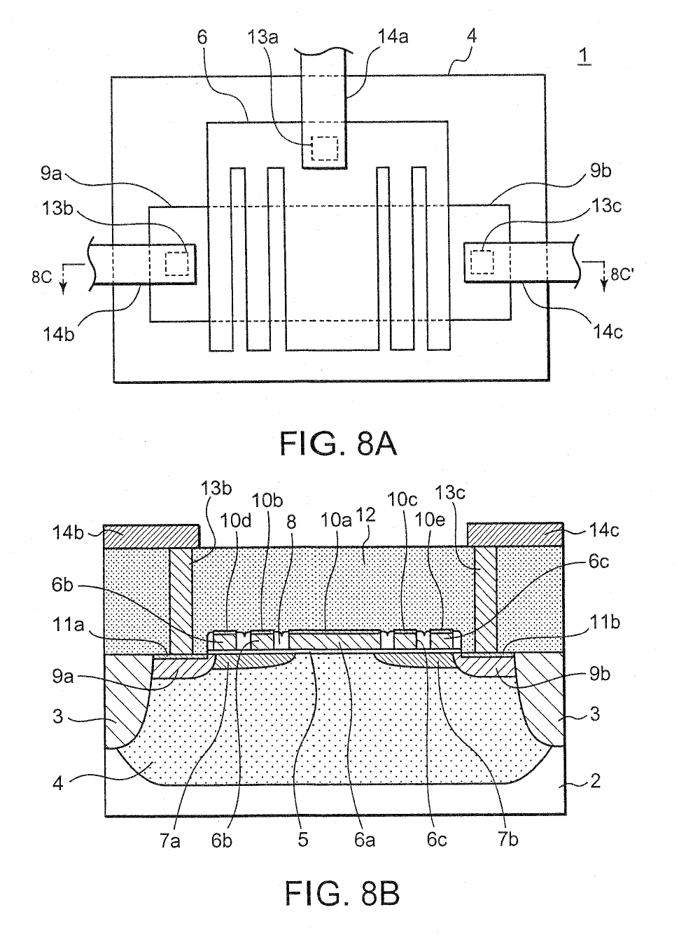

The embodiment 3 of the present invention will now be described using the drawings. FIGS. 8A and 8B schematically show the configuration of the semiconductor apparatus according to the embodiment 3 of the present invention, wherein FIG. 8A is a partial plan view and FIG. 8B is a partial sectional view of a section of 8C-8C′. In the semiconductor apparatus according to the embodiment 3, further one sub-gate 6d and one sub-gate 6e are formed outside the sub-gates 6b, 6c. Other respects of configuration are same as those of the embodiment 1. The configuration may also be applied to the embodiment 2. According to the embodiment 3, a transistor in which the lengths of LDD layers 7a, 7b are further increased can be formed.

### Embodiment 4

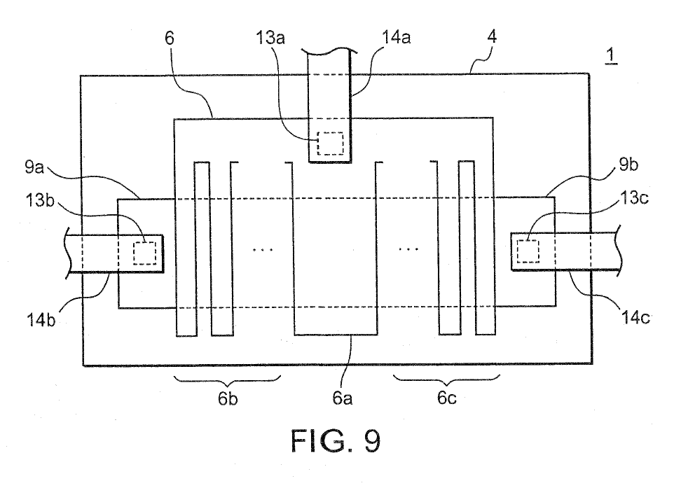

The embodiment 4 of the present invention will now be described using the drawings. FIG. 9 is a partial plan view schematically showing the configuration of the semiconductor apparatus according to the embodiment 4 of the present invention. In the semiconductor apparatus according to the embodiment 4, two or more sub-gates 6b and two or more sub-gates 6c are placed next to the main gate 6a on both sides. Namely, the number of sub-gates 6b, 6c can be freely set for obtaining a desired characteristic. It is not necessary to equalize the number of sub-gates 6b on the source side and the number of sub-gates 6c on the drain side. Other respects of configuration are same as those of the embodiment 1. The configuration may be applied to the embodiment 2. According to the embodiment 4, the lengths of the LDD layers 7a, 7b can be freely set under the sub-gates 6b, 6c for obtaining a desired characteristic.

### Embodiment 5

The embodiment 5 of the present invention will now be described. In the semiconductor apparatus according to the embodiment 5, the distance between the main gate and the sub-gate is controlled to change the degree of contact of the side wall associated with the main gate and the sub-gate. Other respects of configuration are same as those of the embodiment 1. According to the embodiment 5, the thickness of the side wall as a mask for the source/drain layer can be controlled. Namely, the degree of implantation of ions into the source/drain layer can be freely changed, whereby the breakdown resisting pressure, the snap-back resisting pressure and the on-current can be freely controlled.

### Embodiment 6

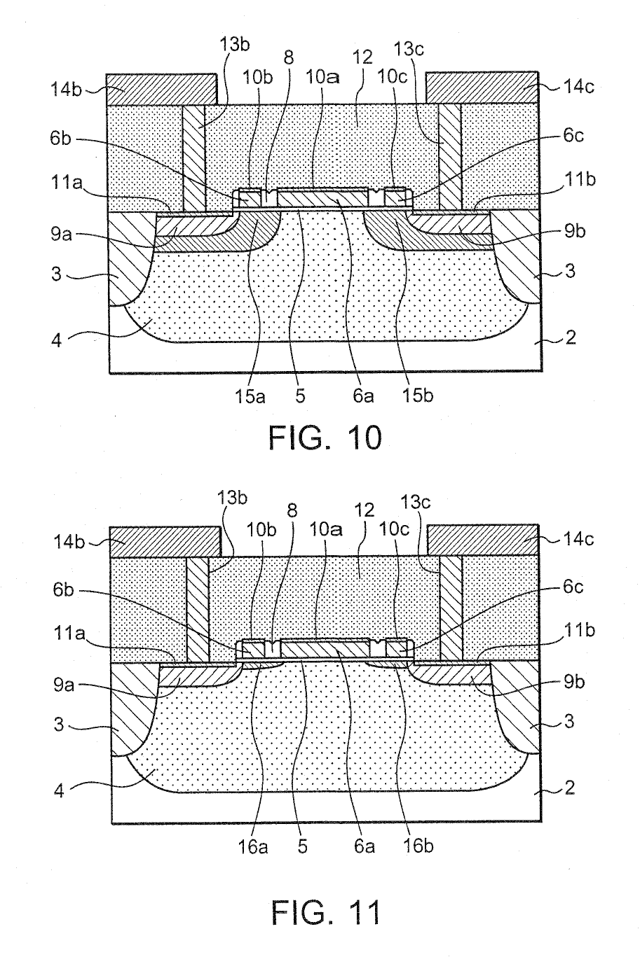

The embodiment 6 of the present invention will now be described using the drawings. FIG. 10 is a partial sectional view schematically showing the configuration of the semiconductor apparatus according to the embodiment 6 of the present invention. In the semiconductor apparatus according to the embodiment 6, double diffused drain (DDD) layers 15a, 15b are used instead of the LDD layers. Other respects of configuration are same as those of the embodiment 1. According to the embodiment 6, a transistor having a further high breakdown resisting pressure and snap-back resisting pressure can be formed.

### Embodiment 7

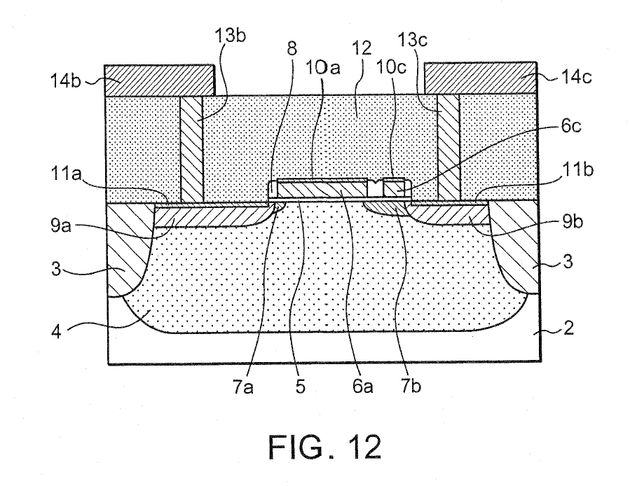

The embodiment 7 of the present invention will now be described using the drawings. FIG. 11 is a partial sectional view schematically showing the configuration of the semiconductor apparatus according to the embodiment 7 of the present invention. In the semiconductor apparatus according to the embodiment 7, extension layers 16a, 16b are used instead of the LDD layers. Other respects of configuration are same as those of the embodiment 1. According to the embodiment 7, a transistor having a shallow junction and having a high snap-back resisting pressure can be formed.

### Embodiment 8

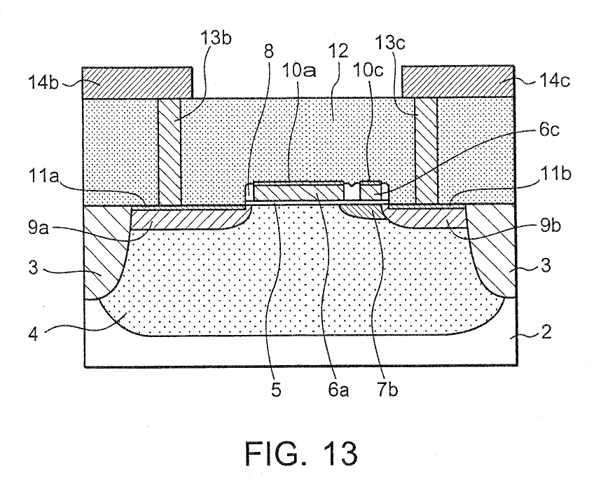

The embodiment 8 of the present invention will now be described using the drawings. FIG. 12 is a partial sectional view schematically showing the configuration of the semiconductor apparatus according to the embodiment 8 of the present invention. FIG. 13 is a partial sectional view schematically showing an alteration of the configuration of the semiconductor apparatus according to the embodiment 8 of the present invention. In the semiconductor apparatus according to the embodiment 8, a transistor made to have a one-way channel by forming the sub-gate 6C only on one side (drain side) is formed. As shown in FIG. 13, a transistor made to have a one-way channel by placing the LDD layer 7b (in place of which the DDD layer or extension layer may be used) only on one side (drain side) is formed. Other respects of configuration are same as those of the embodiment 1.

### Embodiment 9

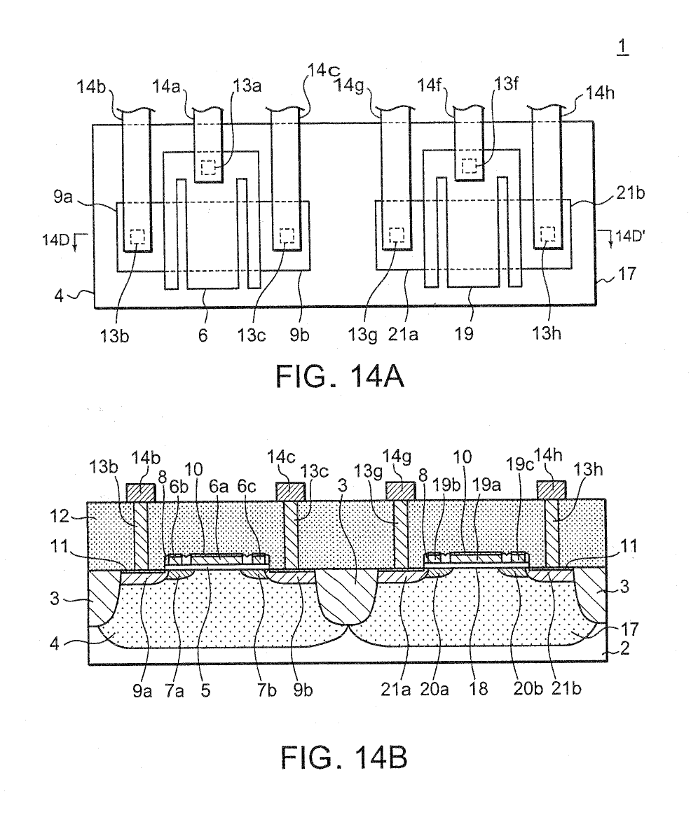

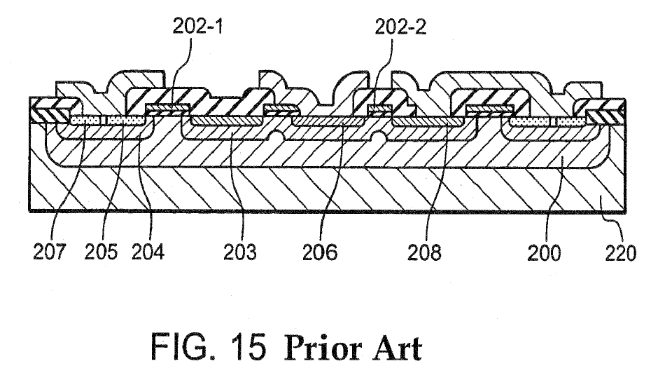

The embodiment 9 of the present invention will now be described using the drawings. FIGS. 14A and 14B schematically show the configuration of the semiconductor apparatus according to the embodiment 9 of the present invention, wherein FIG. 14A is a partial plan view and FIG. 14B is a partial sectional view of a section of D-D′. In the semiconductor apparatus according to the embodiment 9, an NMOS type transistor and a PMOS type transistor are arranged side by side. The configuration on the NMOS type transistor is same as that of the embodiment 1. On the PMOS type transistor side, the well layer is an N well 17, the LDD layers are P− type LDD layers 20a, 20b, and the source/drain layers are P+ type source/drain layers 21a, 21b. Other respects of configuration are same as those of the embodiment 1.

### Embodiment 10

The embodiment 10 of the present invention will now be described. In the semiconductor apparatus according to the embodiment 10, transistors in the semiconductor apparatuses according to embodiments 1 to 9 are combined with transistors having mutually different breakdown resisting pressures. According to the embodiment 10, a mixed device coping with different power supply voltages can be obtained.

What is claimed is:

1. A method of forming a MOS transistor, comprising:
forming a conductive film over a semiconductor substrate;
selectively removing said film to leave a continuous pattern of said film having a main gate portion, a sub-gate portion and a connection portion, said main gate portion and said sub-gate portion being adjacent to each other with a space therebetween where said film was removed;
forming a source/drain region on said substrate; and
forming an impurity diffusion region placed continuously from the end of said source/drain region to near the end of said main gate under said sub-gate, said impurity region having a conductivity type which is the same as that of said source/drain region and having an impurity concentration lower than that of said source/drain region.

2. The method as claimed in claim 1, wherein the source/drain region is formed using the conductive film as a mask.

3. The method as claimed in claim 1, wherein the sub-gate portion comprises sub-gates formed next to said main gate on both sides of said main gate.

4. The method as claimed in claim 3, wherein a number of said sub-gates next to said main gate on one side is different from the number of said sub-gates formed on the other side.

5. The method as claimed in claim 1, wherein said sub-gate is placed next to said main gate only on the drain side.

6. The method as claimed in claim 5, wherein said impurity diffusion region is formed only on the drain side.

7. The method as claimed in claim 1, wherein said impurity diffusion region is a lightly doped drain (LDD) region.

8. The method as claimed in claim 1, wherein said impurity diffusion region is a double diffused drain (DDD) layer.

9. The method as claimed in claim 1, wherein said impurity diffusion is an extension region.

10. The method as claimed in claim 1, further comprising a side wall formed between said main gate and said sub-gate not to link said main gate with said sub-gate.

11. The method as claimed in claim 1, further comprising a side wall formed between said main gate and said sub-gate to link said main gate with said sub-gate.

12. The method as claimed in claim 1, further comprising a second source/drain region formed in said impurity diffusion region and between said main gate and said sub-gate.

13. The method as claimed in claim 12, further comprising a silicide layer placed on the surface of said second source/drain region.

14. The method as claimed in claim 1, wherein said transistor is an NMOS type transistor or PMOS type transistor.

15. The method as claimed in claim 14, wherein said transistor is formed on a semiconductor device having transistors having mutually different breakdown resisting pressures.

16. The method as claimed in claim 15, wherein said substrate is a P type silicon substrate or N type silicon substrate.

17. The method as claimed in claim 1, wherein the impurity diffusion region is formed using the conductive film as a mask.

18. A method of forming a MOS transistor, comprising:
forming a semiconductor substrate of a first conductivity type;
forming an element isolation region on said semiconductor substrate to define an element formation region;
forming a main gate and at least one sub-gate on said element formation region, said at least one sub-gate being adjacent to said main gate, said at least one sub-gate and said main gate being formed from a single unitary conductive element so that the main gate and the at least one sub-gate are in direct contact at a first portion and are separated at a second portion in a same plane;
forming at least one source/drain region of a second conductivity type between said sub gate and said element isolation region, said second conductivity type being different from said first conductivity type; and
forming at least one impurity diffusion region of said second conductivity type between said source/drain region and said main gate under said sub-gate, said impurity diffusion region having an impurity concentration lower than that of said source/drain region.
